(19) United States
(12) Patent Application Publication
(10) Pub. No.: US 2026/0255671 A1
(43) Pub. Date: Aug. 27, 2026

(54) SEMICONDUCTOR DEVICE

(71) Applicant: Samsung Electronics Co., Ltd., Suwon-si (KR)

(72) Inventors: Jiwoo Min, Suwon-si (KR); Byungho Moon, Suwon-si (KR); Donghoon Hwang, Suwon-si (KR)

(73) Assignee: Samsung Electronics Co., Ltd., Suwon-si (KR)

(21) Appl. No.: 19/275,115

(22) Filed: Jul. 21, 2025

(30) Foreign Application Priority Data
Feb. 25, 2025 (KR) 10-2025-0024034

(51) Int. Cl. H10D 84/85; H10D 84/01

(52) U.S. Cl. CPC H10D 84/856; H10D 84/0188; H10D 84/851

(57) ABSTRACT

A semiconductor device includes first and second lower patterns protruding from an upper surface of a substrate in a first direction, a first trench between the lower patterns, plural first nano sheets stacked on the first lower pattern, plural second nano sheets stacked on the second lower pattern, a first gate electrode surrounding the first nano sheets, a second gate electrode surrounding the second nano sheets, a first field insulating film in the trench, an insulating structure penetrating the field insulating film and the substrate in the first direction and including a buried portion embedded in the field insulating film and the substrate, and a gate separation structure extending in the first direction between the first and second gate electrodes and disposed on the insulating structure. The buried portion may have a width in a second direction that decreases from a top portion toward a bottom portion.

### CROSS-REFERENCE TO RELATED APPLICATIONS

This present application claims priority to and the benefit under 35 U.S.C. § 119(a)-(d) of Korean Patent Application No. 10-2025-0024034, filed on Feb. 25, 2025, in the Korean Intellectual Property Office, the entire disclosure of which is incorporated herein by reference.

### BACKGROUND

### Technical Field

The present disclosure relates to a semiconductor device.

### Description of the Related Art

A semiconductor device is a core component used to control or amplify electric signals in an electronic device, and various types of semiconductor devices may be manufactured. For example, a memory device may mainly be used to store and retrieve data, and a non-memory device may be used to control or amplify electric signals. As a core element of an electronic device, a semiconductor device plays an important role in diverse fields, such as computers, communication equipment, consumer electronics, and the like.

With the advancement of industries, performance and functionality requirements for electronic devices are increasing. Accordingly, high-performance characteristics of semiconductor devices are essentially demanded, and the degree of integration of semiconductor devices is increasing to meet these demands. Various methods have been studied to form a semiconductor device having excellent performance and enhanced integration density.

### SUMMARY

The problem to be solved by the present disclosure is to provide a semiconductor device with improved mechanical reliability.

According to some embodiments of the present disclosure for solving the above technical problem, a semiconductor device may include a substrate, a first lower pattern and a second lower pattern protruding from an upper surface of the substrate in a first direction substantially perpendicular to the upper surface of the substrate, a first trench between the first lower pattern and the second lower pattern, a plurality of first nano sheets stacked on the first lower pattern, a plurality of second nano sheets stacked on the second lower pattern and spaced apart in the first direction, a first gate electrode surrounding the plurality of first nano sheets, and a second gate electrode surrounding the plurality of second nano sheets, a first field insulating film in the first trench, an insulating structure penetrating the first field insulating film and the upper surface of the substrate in the first direction, the insulating structure comprising a buried portion embedded in the first field insulating film and in the substrate, and a gate separation structure extending in the first direction between the first gate electrode and the second gate electrode and disposed on the insulating structure. The buried portion may have a width in a second direction perpendicular to the first direction that decreases from a top portion toward a bottom portion of the buried portion.

According to some embodiments of the present disclosure for solving the above technical problem, a semiconductor device may include a substrate, a first lower pattern and a second lower pattern protruding in a first direction from an upper surface of the substrate, the first lower pattern and the second lower pattern being spaced apart from each other in a second direction perpendicular to the first direction, a first field insulating film on the upper surface of the substrate between the first lower pattern and the second lower pattern, a plurality of first nano sheets stacked on the first lower pattern, a plurality of second nano sheets stacked on the second lower pattern and spaced apart in the first direction, a first gate electrode surrounding the plurality of first nano sheets, and a second gate electrode surrounding the plurality of second nano sheets; an insulating structure that penetrates the first field insulating film and the upper surface of the substrate in the first direction, and a gate separation structure extending in the first direction between the first gate electrode and the second gate electrode. The insulating structure may include a buried portion embedded in the first field insulating film and in the substrate and having a width in the second direction that decreases from a top portion toward a bottom portion thereof, and a protruding portion on the buried portion and protruding from the first field insulating film. The gate separation structure may be on the protruding portion.

According to some embodiments of the present disclosure for solving the above technical problem, a semiconductor device may include a substrate, a first lower pattern and a second lower pattern protruding from an upper surface of the substrate in a first direction substantially perpendicular to the upper surface of the substrate, a first trench having a first width between the first lower pattern and the second lower pattern, a second trench having a second width smaller than the first width and spaced apart from the first trench in a second direction perpendicular to the first direction, a first lower channel pattern and a first upper channel pattern stacked on the first lower pattern to be spaced apart in the first direction, a second lower channel pattern and a second upper channel pattern respectively stacked on the second lower pattern to be spaced apart in the first direction, a first lower gate electrode surrounding the first lower channel pattern and a first upper gate electrode surrounding the first upper channel pattern, a second lower gate electrode surrounding the second lower channel pattern and a second upper gate electrode surrounding the second upper channel pattern, a first field insulating film in the first trench and a second field insulating film in the second trench, an insulating structure penetrating the first field insulating film and the upper surface of the substrate in the first direction, and a gate separation structure extending in the first direction and disposed on the insulating structure. The insulating structure may include a buried portion embedded in the first field insulating film and in the substrate and having a width in the second direction that decreases from a top portion toward a bottom portion thereof, and a protruding portion on the buried portion to protrude from the first field insulating film and having a rounded top surface. The gate separation structure may penetrate through an upper surface of the protruding portion.

According to some embodiments, provided is a method for manufacturing a semiconductor device comprising: providing a substrate; providing a first lower pattern and a second lower pattern protruding from an upper surface of the substrate in a first direction substantially perpendicular to the upper surface of the substrate; providing a first trench between the first lower pattern and the second lower pattern; providing a plurality of first nano sheets stacked on the first lower pattern; providing a plurality of second nano sheets stacked on the second lower pattern and spaced apart in the first direction; providing a first gate electrode surrounding the plurality of first nano sheets, and a second gate electrode surrounding the plurality of second nano sheets; providing a first field insulating film in the first trench; providing an insulating structure penetrating the first field insulating film and the upper surface of the substrate in the first direction, the insulating structure comprising a buried portion embedded in the first field insulating film and in the substrate; and providing a gate separation structure extending in the first direction between the first gate electrode and the second gate electrode and disposed on the insulating structure, wherein the buried portion has a width in a second direction, which is substantially perpendicular to the first direction, that decreases from a top portion toward a bottom portion of the buried portion.

According to some embodiments of the present disclosure, the mechanical reliability of the semiconductor device may be improved.

### BRIEF DESCRIPTION OF THE DRAWINGS

FIG. 1 illustrates a layout diagram of a semiconductor device according to some embodiments of the present disclosure.

FIG. 2 is a cross-sectional view illustrating the semiconductor device of FIG. 1, taken along line A-A′ thereof.

FIG. 3 is a cross-sectional view illustrating the semiconductor device of FIG. 1, taken along line B-B′ thereof.

FIG. 4 is a cross-sectional view illustrating a semiconductor device according to some embodiments of the present disclosure.

FIG. 5 is a cross-sectional view illustrating a semiconductor device according to some embodiments of the present disclosure.

FIG. 6 is a cross-sectional view illustrating a semiconductor device according to some embodiments of the present disclosure.

FIGS. 7 to 16 are diagrams illustrating a method of manufacturing a semiconductor device according to some embodiments of the present disclosure.

### DETAILED DESCRIPTION

Hereinafter, a semiconductor device according to some embodiments of the present disclosure will be described in detail with reference to the drawings.

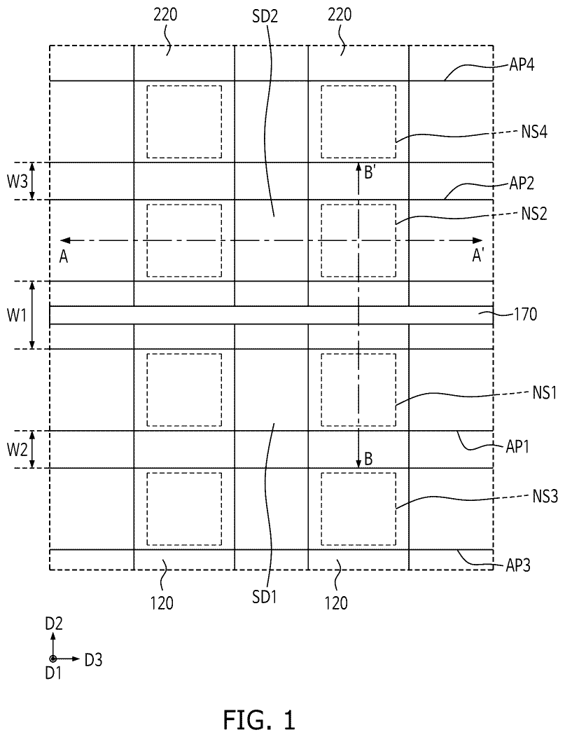

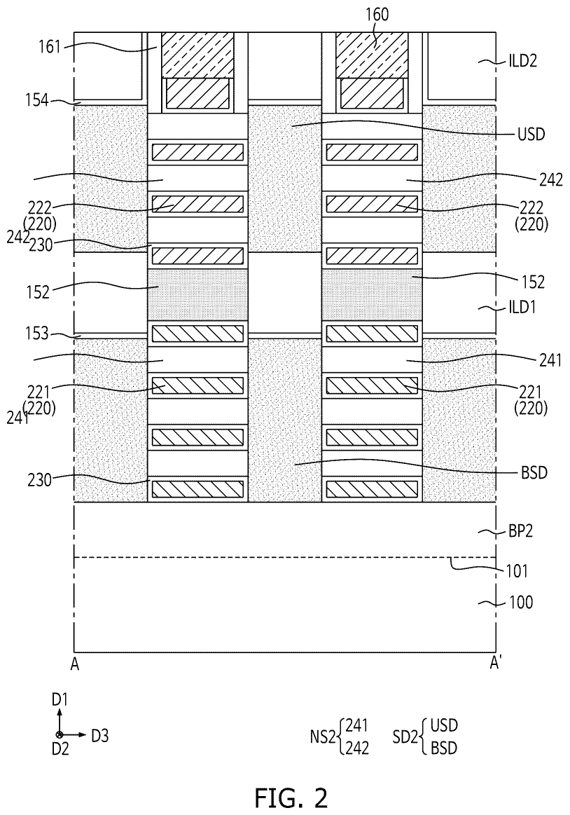

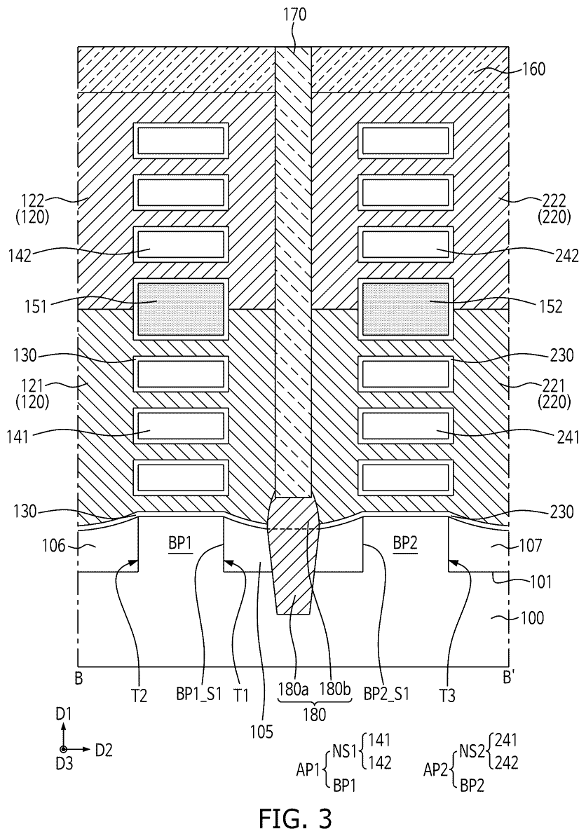

FIG. 1 illustrates a layout diagram of a semiconductor device according to some embodiments of the present disclosure. FIG. 2 is a cross-sectional view illustrating the semiconductor device of FIG. 1, taken along line A-A′ thereof. FIG. 3 is a cross-sectional view illustrating the semiconductor device of FIG. 1, taken along line B-B′ thereof.

Referring to FIGS. 1 to 3, a semiconductor device according to some embodiments of the present disclosure may include a substrate 100, first to fourth active patterns AP1, AP2, AP3, AP4, first to third field insulating films 105, 106, 107, a first gate electrode 120, a second gate electrode 220, an insulating structure 180, a gate separation structure 170, a capping pattern 160, and so forth.

The substrate 100 may be bulk silicon or silicon-on-insulator (SOI).

Alternatively, the substrate 100 may include silicon germanium (SiGe), silicon germanium on insulator (SGOI), indium antimonide, lead telluride compounds, indium arsenide, indium phosphide, gallium arsenide, or gallium antimonide, but is not limited thereto.

The first active pattern AP1 may be disposed on the substrate 100. The first active pattern AP1 may extend in a third direction D3. The first active pattern AP1 may include a first lower pattern BP1 and a plurality of first nano sheets NS1.

The first lower pattern BP1 may protrude from the substrate 100 in a first direction D1. The plurality of first nano sheets NS1 may be disposed on the first lower pattern BP1. The plurality of first nano sheets NS1 may be spaced in the first direction D1 from the first lower pattern BP1. Each of the plurality of first nano sheets NS1 may be spaced from one another in the first direction D1. Here, the first direction D1 may be perpendicular to an upper surface 101 of the substrate 100. A second direction D2 and the third direction D3 each may be parallel to the upper surface 101 of the substrate 100. The first direction D1 may intersect (for example, be perpendicular to) each of the second direction D2 and the third direction D3.

The plurality of first nano sheets NS1 may include a first lower channel pattern 141 and a first upper channel pattern 142. The first upper channel pattern 142 may be spaced apart from the first lower channel pattern 141 in the first direction D1. A first device isolation layer 151 may be disposed between the first lower channel pattern 141 and the first upper channel pattern 142. Each of the first lower channel pattern 141 and the first upper channel pattern 142 may be spaced apart from the first device isolation layer 151 in the first direction D1.

The second active pattern AP2 may be disposed on the substrate 100. The second active pattern AP2 may be spaced apart from the first active pattern AP1 in the second direction D2. The second active pattern AP2 may extend in the third direction D3. The second active pattern AP2 may include a second lower pattern BP2 and a plurality of second nano sheets NS2.

The second lower pattern BP2 may protrude from the substrate 100 in the first direction D1. The plurality of second nano sheets NS2 may be disposed on the second lower pattern BP2. The plurality of second nano sheets NS2 may be spaced apart in the first direction D1 from the second lower pattern BP2. Each of the plurality of second nano sheets NS2 may be spaced apart from one another in the first direction D1.

The plurality of second nano sheets NS2 may include a second lower channel pattern 241 and a second upper channel pattern 242. The second upper channel pattern 242 may be spaced apart from the second lower channel pattern 241 in the first direction D1. A second device isolation layer 152 may be disposed between the second lower channel pattern 241 and the second upper channel pattern 242. Each of the second lower channel pattern 241 and the second upper channel pattern 242 may be spaced apart from the second device isolation layer 152 in the first direction D1.

Each of the first device isolation layer 151 and the second device isolation layer 152 may include an insulating material. For example, each of the first device isolation layer 151 and the second device isolation layer 152 may include at least one of silicon nitride (SiN), silicon oxynitride (SiON), silicon boron carbon nitride (SiBCN), silicon carbon nitride (SiCN), silicon oxide nitride (SiON), and combinations thereof. However, materials constituting the first device isolation layer 151 and the second device isolation layer 152 are not limited thereto.

The third active pattern AP3 may be disposed on the substrate 100. The third active pattern AP3 may be spaced apart from the first active pattern AP1 in the second direction D2. The third active pattern AP3 may be positioned on an opposite side of the first active pattern AP1, relative to the second active pattern AP2. The third active pattern AP3 may extend in the third direction D3. The third active pattern AP3 may include a third lower pattern and a plurality of third nano sheets NS3.

The plurality of third nano sheets NS3 may be disposed on the third lower pattern. The plurality of third nano sheets NS3 may be spaced apart from the third lower pattern in the first direction D1. Each of the third nano sheets NS3 may be spaced apart in the first direction D1.

The fourth active pattern AP4 may be disposed on the substrate 100. The fourth active pattern AP4 may be spaced apart from the second active pattern AP2 in the second direction D2. The fourth active pattern AP4 may be positioned on an opposite side of the second active pattern AP2, relative to the first active pattern AP1. The fourth active pattern AP4 may extend in the third direction D3. The fourth active pattern AP4 may include a fourth lower pattern and a plurality of fourth nano sheets NS4.

The plurality of fourth nano sheets NS4 may be disposed on the fourth lower pattern. The plurality of fourth nano sheets NS4 may be spaced apart from the fourth lower pattern in the first direction D1. Each of the fourth nano sheets NS4 may be spaced apart in the first direction D1.

Each of the first lower pattern BP1 and the second lower pattern BP2 may be formed by etching a portion of the substrate 100. However, this is not limiting, and, for example, each of the first lower pattern BP1 and the second lower pattern BP2 may include an epitaxial layer grown from the substrate 100. Each of the first lower pattern BP1 and the second lower pattern BP2 may include silicon (Si) or germanium (Ge) as an elemental semiconductor material. In addition, each of the first lower pattern BP1 and the second lower pattern BP2 may include a compound semiconductor. For example, a lower pattern BP may include a IV-IV compound semiconductor or a III-V compound semiconductor. The IV-IV compound semiconductor may, for example, be a binary compound or a ternary compound including at least two among carbon (C), silicon (Si), germanium (Ge), and tin (Sn). The description of the first lower pattern BP1 and the second lower pattern BP2 may be substantially equally applied to the third lower pattern and the fourth lower pattern.

Each of the first nano sheets NS1 and the second nano sheets NS2 may include one of silicon (Si) or silicon germanium (SiGe) as an elemental semiconductor material, a IV-IV compound semiconductor, or a III-V compound semiconductor. The first nano sheets NS1 may include the same material as or a different material from the first lower pattern BP1. The second nano sheets NS2 may include the same material as or a different material from the second lower pattern BP2. The descriptions of the first nano sheets NS1 and the second nano sheets NS2 may be substantially equally applied to the third nano sheets NS3 and the fourth nano sheets NS4.

In some embodiments, the substrate 100 may include an insulating material. For example, the substrate 100 may be an insulating substrate. A boundary surface between the substrate 100 and the first lower pattern BP1 and between the substrate 100 and the second lower pattern BP2 may be distinct.

In some embodiments, each of the first lower pattern BP1 and the second lower pattern BP2 may include an insulating material. Although not shown, in some embodiments, the semiconductor device may further include a lower gate contact that penetrates the first lower pattern BP1 and/or a lower gate contact that penetrates the second lower pattern BP2.

A first trench T1 may be disposed between the first lower pattern BP1 and the second lower pattern BP2. The first trench T1 may be defined by the upper surface 101 of the substrate 100, a first side surface BP1_S1 of the first lower pattern BP1, and a first side surface BP2_S1 of the second lower pattern BP2. A first field insulating film 105 and the insulating structure 180 may be disposed on the first trench T1. The first trench T1 may have a first width W1. That is, the first field insulating film 105 filling the inside of the first trench T1 may have the first width W1. In other words, the distance between the first side surface BP1_S1 of the first lower pattern BP1 and the first side surface BP2_S1 of the second lower pattern BP2 may correspond to the first width W1.

A second trench T2 may be disposed on one side of the first trench T1. The second trench T2 may be spaced apart from the first trench T1 in the second direction D2. A second field insulating film 106 may be disposed on the second trench T2. The second field insulating film 106 may fill the second trench T2.

The second trench T2 may have a second width W2. That is, the second field insulating film 106 filling the inside of the second trench T2 may have the second width W2. The second width W2 may correspond to the distance between the first active pattern AP1 and the third active pattern AP3. The second width W2 may be smaller than the first width W1.

A third trench T3 may be disposed on the other side of the first trench T1. The third trench T3 may be spaced apart from the first trench T1 in the second direction D2. A third field insulating film 107 may be disposed on the third trench T3. The third field insulating film 107 may fill the third trench T3.

The third trench T3 may have a third width W3. That is, the third field insulating film 107 filling the inside of the third trench T3 may have the third width W3. The third width W3 may correspond to the distance between the second active pattern AP2 and the fourth active pattern AP4. The third width W3 may be smaller than the first width W1. In some embodiments, the third width W3 may be the same as the second width W2.

Each of the first to third field insulating films 105, 106, 107 may have a rounded upper surface. For example, each of the first to third field insulating films 105, 106, 107 may have a convex curved surface facing downward. Part of each upper surface of the first to third field insulating films 105, 106, 107 may be located at a level lower than the upper surfaces of the first and second lower patterns BP1, BP2.

Each of the first to third field insulating films 105, 106, 107 may include, for example, an oxide, a nitride, an oxynitride, or a combination thereof. Although each of the first to third field insulating films 105, 106, 107 is illustrated as a single film, this is merely for convenience of explanation and is not limiting. For example, each of the first to third field insulating films 105, 106, 107 may be formed of multiple films.

The first gate electrode 120 may be disposed on the first field insulating film 105, the second field insulating film 106, and the first lower pattern BP1. The first gate electrode 120 may intersect the first active pattern AP1. The first gate electrode 120 may surround the first nano sheets NS1. The first gate electrode 120 may be disposed among the plurality of first nano sheets NS1. The first gate electrode 120 may be disposed between the first nano sheet NS1 positioned at the lowermost level among the plurality of first nano sheets NS1 and the first lower pattern BP1.

The first gate electrode 120 may include a first lower gate electrode 121 and a first upper gate electrode 122. The first lower gate electrode 121 may surround the first lower channel pattern 141, and the first upper gate electrode 122 may surround the first upper channel pattern 142. The first upper gate electrode 122 may be disposed on an upper surface of the first lower gate electrode 121. The first device isolation layer 151 may be disposed between the first lower gate electrode 121 and the first upper gate electrode 122. In some embodiments, a gate isolation layer may be disposed between the first lower gate electrode 121 and the first upper gate electrode 122.

The second gate electrode 220 may be disposed on the first field insulating film 105, the third field insulating film 107, and the second lower pattern BP2. The second gate electrode 220 may intersect the second active pattern AP2. The second gate electrode 220 may surround the second nano sheets NS2. The second gate electrode 220 may be disposed among the plurality of second nano sheets NS2. The second gate electrode 220 may be disposed between the second nano sheet NS2 positioned at the lowermost level among the plurality of second nano sheets NS2 and the second lower pattern BP2.

The second gate electrode 220 may include a second lower gate electrode 221 and a second upper gate electrode 222. The second lower gate electrode 221 may surround the second lower channel pattern 241, and the second upper gate electrode 222 may surround the second upper channel pattern 242. The second upper gate electrode 222 may be disposed on an upper surface of the second lower gate electrode 221. The second device isolation layer 152 may be disposed between the second lower gate electrode 221 and the second upper gate electrode 222. In some embodiments, a gate isolation layer may be disposed between the second lower gate electrode 221 and the second upper gate electrode 222.

The first gate electrode 120 may be spaced apart from the second gate electrode 220 in the second direction D2. The first gate electrode 120 may overlap the second gate electrode 220 in the second direction D2. A gate separation structure 170 may be disposed between the first gate electrode 120 and the second gate electrode 220.

The first lower gate electrode 121 and the first upper gate electrode 122 may include different materials. The second lower gate electrode 221 and the second upper gate electrode 222 may include different materials. The first lower gate electrode 121 and the second lower gate electrode 221 may include the same material. Also, the first upper gate electrode 122 and the second upper gate electrode 222 may include the same material.

For example, each of the first gate electrode 120 and the second gate electrode 220 may include at least one of a metal, a metal alloy, a conductive metal nitride, a metal silicide, a doped semiconductor material, a conductive metal oxide, or a conductive metal oxynitride. For example, each of the first gate electrode 120 and the second gate electrode 220 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbon nitride (TiAIC-N), titanium aluminum carbide (TiAlC), titanium carbide (TiC), tantalum carbon nitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but is not limited thereto. A conductive metal oxide or a conductive metal oxynitride may be an oxidized form of the foregoing materials, but is not limited thereto.

Although each of the first gate electrode 120 and the second gate electrode 220 is illustrated as a single film, it is not limited thereto. For example, each of the first gate electrode 120 and the second gate electrode 220 may include a work function adjustment film for adjusting a work function and a filling conductive film that fills the space formed by the work function adjustment film. The work function adjustment film may include, for example, at least one of titanium nitride (TiN), tantalum nitride (TaN), titanium carbide (TiC), tantalum carbide (TaC), titanium aluminum carbide (TiAlC), or combinations thereof. The filling conductive film may include, for example, tungsten (W) or aluminum (Al).

A first gate insulating film 130 may be disposed between the first gate electrode 120 and the first nano sheets NS1 and between the first gate electrode 120 and the first lower pattern BP1. The first gate insulating film 130 may surround the first nano sheets NS1 and the first device isolation layer 151. For example, the first gate insulating film 130 may surround all four sides of each first nano sheet NS1.

A second gate insulating film 230 may be disposed between the second gate electrode 220 and the second nano sheets NS2 and between the second gate electrode 220 and the second lower pattern BP2. The second gate insulating film 230 may surround the second nano sheets NS2 and the second device isolation layer 152. For example, the second gate insulating film 230 may surround all four sides of each second nano sheet NS2.

Although each of the first gate insulating film 130 and the second gate insulating film 230 is illustrated as a single film, each may include multiple films. For example, each of the first gate insulating film 130 and the second gate insulating film 230 may include an interfacial insulating film and a high-k insulating film. The interfacial insulating film may include a silicon oxide. The high-k insulating film may include a high-k material having a dielectric constant higher than that of the interfacial insulating film. For example, the high-k insulating film may include one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, the first gate insulating film 130 and the second gate insulating film 230 may include the same material.

A capping pattern 160 may be disposed on upper surfaces of the first gate electrode 120 and the second gate electrode 220. The capping pattern 160 may cover the upper surfaces of the first gate electrode 120 and the second gate electrode 220. The capping pattern 160 may contact a gate spacer 161. For example, a side surface of the capping pattern 160 may contact the gate spacer 161. However, the present disclosure is not limited thereto. For example, a side surface of the capping pattern 160 may contact a second etch stop layer 154, and a lower surface of the capping pattern 160 may contact the gate spacer 161.

The capping pattern 160 may include, for example, at least one of silicon nitride (SiN), silicon oxynitride (SiON), silicon carbon nitride (SiCN), silicon oxycarbonitride (SiOCN), or combinations thereof. The capping pattern 160 may include a material that has an etch selectivity relative to a second interlayer insulating film ILD2.

The gate spacer 161 may be disposed on a side surface of the second gate electrode 220 and on a side surface of the capping pattern 160. For example, the gate spacer 161 may extend along the side surface of the second gate electrode 220 disposed on an upper portion of the uppermost second nano sheet NS2 among the plurality of second nano sheets NS2.

The gate spacer 161 may include, for example, at least one of silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), or combinations thereof. Although the gate spacer 161 is illustrated as a single film, the present disclosure is not limited thereto.

The gate separation structure 170 may extend in the first direction D1. The gate separation structure 170 may be disposed between the first gate electrode 120 and the second gate electrode 220. The gate separation structure 170 may penetrate the first gate electrode 120 and the second gate electrode 220 in the first direction D1. The gate separation structure 170 may separate the first gate electrode 120 and the second gate electrode 220.

The gate separation structure 170 may extend in the third direction D3. The gate separation structure 170 may intersect a plurality of gate electrodes spaced in the third direction D3. In some embodiments, the gate separation structure 170 may be configured as a plurality of structures corresponding respectively to the plurality of gate electrodes spaced in the third direction D3.

The gate separation structure 170 may include an insulating material. The gate separation structure 170 may include, for example, at least one of silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), or combinations thereof.

The insulating structure 180 may include a buried portion 180a and a protruding portion 180b. The insulating structure 180 may penetrate the first field insulating film 105 and the upper surface 101 of the substrate 100 in the first direction D1.

Part of the buried portion 180a may be located inside the first field insulating film 105 filling the first trench T1, and a remaining part of the buried portion 180a may be located inside the substrate 100. The buried portion 180a may be embedded in the first field insulating film 105 and the substrate 100.

The buried portion 180a may have a tapered shape. For example, the width in the second direction D2 of the buried portion 180a may decrease from an upper surface thereof toward a lower surface thereof. The width in the second direction D2 of the upper surface of the buried portion 180a may be larger than the width in the second direction D2 of the lower surface of the buried portion 180a.

The protruding portion 180b may protrude outward from the first field insulating film 105. The protruding portion 180b may protrude upward from the first field insulating film 105. For example, the protruding portion 180b may have a rounded upper surface. In some embodiments, the protruding portion 180b may include an angled portion. The protruding portion 180b may have an upwardly convex cross-sectional shape. The protruding portion 180b may be disposed between the first gate electrode 120 and the second gate electrode 220. Further, the protruding portion 180b may be disposed between a lowermost first gate insulating film 130 and a lowermost second gate insulating film 230. The protruding portion 180b and the gate separation structure 170 may prevent electrical conduction between the first gate electrode 120 and the second gate electrode 220.

The insulating structure 180 may include an insulating material. For example, the insulating structure 180 may include at least one of silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), or combinations thereof.

The insulating structure 180 may include a material different from that of the first field insulating film 105. The insulating structure 180 may have an etch selectivity different from that of the material constituting the first field insulating film 105. For example, when the first field insulating film 105 includes silicon oxide (SiO), the insulating structure 180 may include silicon nitride (SiN). However, this is merely an example, and the technical spirit of the present disclosure is not limited thereto.

The gate separation structure 170 may penetrate through an upper surface of the insulating structure 180. A lower surface of the gate separation structure 170 may be disposed on the insulating structure 180. Specifically, the lower surface of the gate separation structure 170 may be located at a level lower than a topmost portion of the insulating structure 180. For example, the lower surface of the gate separation structure 170 may penetrate through the upper surface of the protruding portion 180b of the insulating structure 180. A maximum width of the protruding portion 180b in the second direction D2 may be larger than the width of the gate separation structure 170 in the second direction D2. For example, the maximum width of the protruding portion 180b in the second direction D2 may be larger than the width of the lower surface of the gate separation structure 170 in the second direction D2. That is, the lower surface of the gate separation structure 170 may be positioned inside the protruding portion 180b.

The insulating structure 180 may be disposed on the first field insulating film 105 filling the first trench T1, and the gate separation structure 170 may be disposed on the insulating structure 180. For example, the gate separation structure 170 may be disposed on the protruding portion 180b of the insulating structure 180. In some embodiments, the lower surface of the gate separation structure 170 may be spaced apart from an upper surface of the first field insulating film 105.

A first source/drain pattern SD1 may be disposed on the first active pattern AP1. The plurality of first nano sheets NS1 may be disposed on a side surface of the first source/drain pattern SD1. For example, the first source/drain pattern SD1 may be disposed on one side of the plurality of first nano sheets NS1. The same description for the first source/drain pattern SD1 may be substantially applied to a second source/drain pattern SD2 to be described below.

The second source/drain pattern SD2 may be disposed on the second active pattern AP2. For example, the plurality of second nano sheets NS2 may be disposed on a side surface of the second source/drain pattern SD2. Specifically, the second source/drain pattern SD2 may include an upper source/drain pattern USD disposed on a side surface of the second upper channel pattern 242 and a lower source/drain pattern BSD disposed on a side surface of the second lower channel pattern 241.

A lower surface of the second source/drain pattern SD2 may be disposed on the second lower pattern BP2. Although the lower surface of the second source/drain pattern SD2 is illustrated as being located on the same plane as a bottom surface of the second gate insulating film 230, the present disclosure is not limited thereto. For example, the lower surface of the second source/drain pattern SD2 may be located at a level lower than or higher than the bottom surface of the second gate insulating film 230.

Although not shown, third and fourth source/drain patterns may be disposed on the third and fourth active patterns AP3, AP4, respectively. For example, a plurality of third and fourth nano sheets NS3, NS4 may be respectively disposed on a side surface of each of the third and fourth source/drain patterns. Descriptions of the third and fourth source/drain patterns may be similar to those of the first and second source/drain patterns SD1, SD2.

As descriptions of the first to fourth source/drain patterns may overlap, hereinafter, the second source/drain pattern SD2 will be described primarily.

The second source/drain pattern SD2 may be an epitaxial pattern formed by a selective epitaxial growth process using the second active pattern AP2 as a seed. The second source/drain pattern SD2 may serve as a source/drain of a transistor using the second nano sheets NS2 as a channel region.

The second source/drain pattern SD2 may include a semiconductor material. The second source/drain pattern SD2 may, for example, include elemental semiconductor silicon (Si) or germanium (Ge). Further, the second source/drain pattern SD2 may, for example, include a binary compound or a ternary compound containing at least two of carbon (C), silicon (Si), germanium (Ge), and tin (Sn), or a compound doped with a group-IV element of such compounds. For example, the second source/drain pattern SD2 may include silicon (Si), silicon-germanium (SiGe), germanium (Ge), or silicon carbide (SiC), but is not limited thereto.

The second source/drain pattern SD2 may include an impurity doped into the semiconductor material. The doped impurity may include at least one of boron (B), phosphorus (P), carbon (C), arsenic (As), antimony (Sb), bismuth (Bi), or oxygen (O), but is not limited thereto.

Although the second source/drain pattern SD2 is illustrated as a single film, this is merely for convenience of explanation and is not limiting. In an embodiment, the second source/drain pattern SD2 may include a plurality of films containing different materials. In another embodiment, the second source/drain pattern SD2 may include the same material and have multiple layers of different concentrations of that material.

The upper source/drain pattern USD and the lower source/drain pattern BSD may have different conduction types. For example, the conduction type of the upper source/drain pattern USD may be p-type, and the conduction type of the lower source/drain pattern BSD may be n-type. In another example, the conduction type of the upper source/drain pattern USD may be n-type, and the conduction type of the lower source/drain pattern BSD may be p-type.

A first etch stop layer 153 may be disposed on the lower source/drain pattern BSD. The first etch stop layer 153 may cover an upper surface of the lower source/drain pattern BSD.

A first interlayer insulating film ILD1 may be disposed on the first etch stop layer 153. The first interlayer insulating film ILD1 may be disposed between the upper source/drain pattern USD and the lower source/drain pattern BSD.

A second etch stop layer 154 may be disposed on an upper surface of the upper source/drain pattern USD and on a side surface of the gate spacer 161. The second etch stop layer 154 may cover the upper surface of the upper source/drain pattern USD.

Each of the first etch stop layer 153 and the second etch stop layer 154 may include, for example, at least one of silicon nitride (SiN), silicon oxide (SiO), silicon oxynitride (SiON), silicon oxycarbonitride (SiOCN), silicon boron nitride (SiBN), silicon oxyboron nitride (SiOBN), silicon oxycarbide (SiOC), or combinations thereof. The second etch stop layer 154 may include a material having an etch selectivity relative to a second interlayer insulating film ILD2.

The second interlayer insulating film ILD2 may be disposed on the second etch stop layer 154. Each of the first interlayer insulating film ILD1 and the second interlayer insulating film ILD2 may include, for example, at least one of silicon oxide (SiO), silicon nitride (SiN), silicon oxynitride (SiON), or a low-k material. The low-k material may include, for example, one or more of Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiary ButoSiloxane (DADBS), TriMethylSilil Phosphate (TMSP), Poly TetraFluoroEthylene (PTFE), TOSZ (Tonen SilaZen), FSG (Fluoride Silicate Glass), polypropylene oxide such as polyimide nanofoams, carbon doped silicon oxide (CDO), organo silicate glass (OSG), SiLK, amorphous fluorinated carbon, silica aerogels, silica xerogels, mesoporous silica, or combinations thereof, but the present disclosure is not limited thereto.

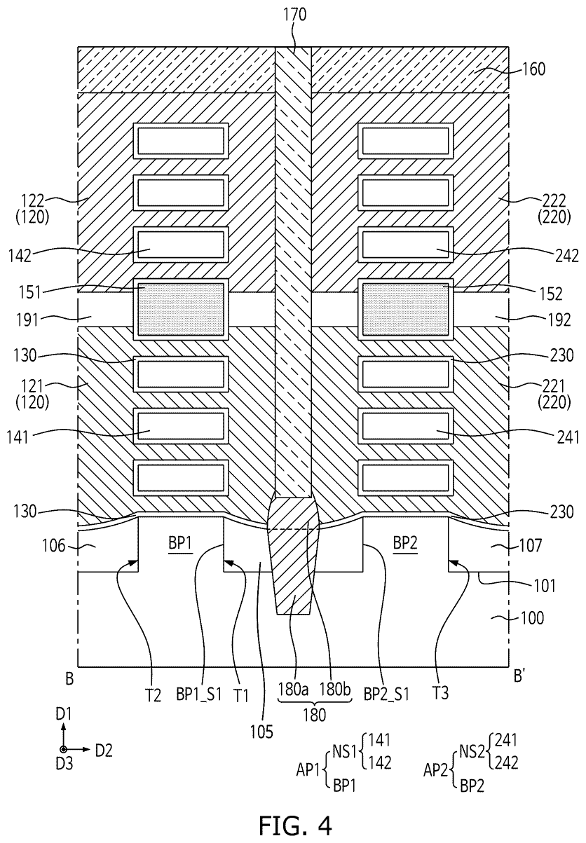

FIG. 4 is a cross-sectional view illustrating a semiconductor device according to some embodiments of the present disclosure. For convenience of explanation, a configuration different from what was described with reference to FIGS. 1 to 3 will be mainly described.

Referring to FIG. 4, a semiconductor device according to some embodiments of the present disclosure may further include a first gate isolation layer 191 and a second gate isolation layer 192.

The first gate isolation layer 191 may be disposed between the first upper gate electrode 122 and the first lower gate electrode 121. The first gate isolation layer 191 may be disposed on a lower surface of the first upper gate electrode 122 and an upper surface of the first lower gate electrode 121. The first gate isolation layer 191 may insulate the first upper gate electrode 122 and the first lower gate electrode 121 from each other.

The second gate isolation layer 192 may be disposed between the second upper gate electrode 222 and the second lower gate electrode 221. The second gate isolation layer 192 may be disposed on a lower surface of the second upper gate electrode 222 and an upper surface of the second lower gate electrode 221. The second gate isolation layer 192 may insulate the second upper gate electrode 222 and the second lower gate electrode 221 from each other.

Each of the first gate isolation layer 191 and the second gate isolation layer 192 may overlap the first device isolation layer 151 and the second device isolation layer 152 in the second direction D2. By the first gate isolation layer 191, different gate voltages may be applied respectively to the first upper channel pattern 142 and the first lower channel pattern 141. By the second gate isolation layer 192, different gate voltages may be applied respectively to the second upper channel pattern 242 and the second lower channel pattern 241.

Each of the first gate isolation layer 191 and the second gate isolation layer 192 may include an insulating material. For example, each of the first gate isolation layer 191 and the second gate isolation layer 192 may include at least one of silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), or combinations thereof.

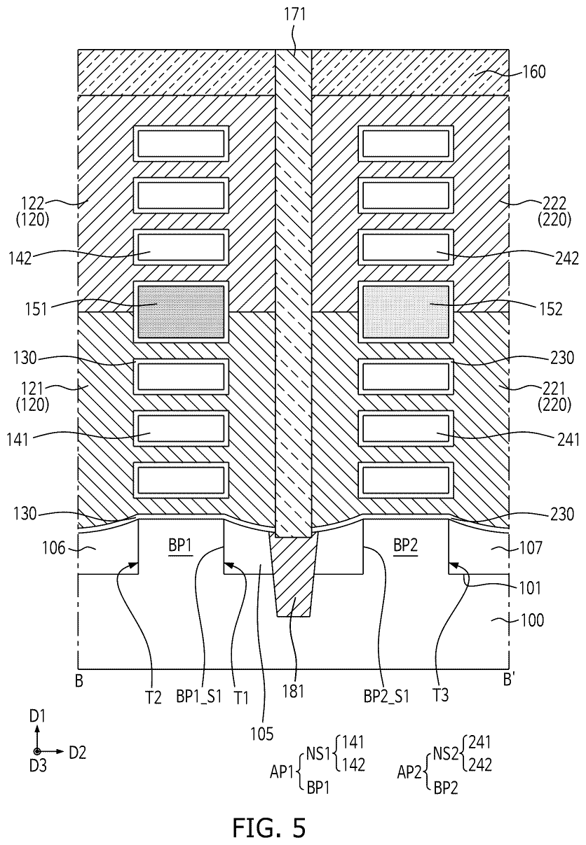

FIG. 5 is a cross-sectional view illustrating a semiconductor device according to some embodiments of the present disclosure. For convenience of explanation, a configuration different from what was described with reference to FIGS. 1 to 3 will be mainly described.

Referring to FIG. 5, a semiconductor device according to some embodiments of the present disclosure may include an insulating structure 181 and a gate separation structure 171, each having shapes different from those of the insulating structure 180 and the gate separation structure 170 in FIG. 3.

The insulating structure 181 may be disposed inside the first trench T1. The insulating structure 181 may be embedded in the first field insulating film 105. The insulating structure 181 may overlap the first field insulating film 105 in the second direction D2. An upper surface of the insulating structure 181 may be coplanar with an upper surface of the first field insulating film 105. For example, the upper surface of the insulating structure 181 and the upper surface of the first field insulating film 105 may form a rounded surface. Specifically, the upper surface of the insulating structure 181 and the upper surface of the first field insulating film 105 may be a convex curved surface facing downward.

The insulating structure 181 may not include a protruding portion but may include only a buried portion. The insulating structure 181 may have a tapered shape.

For example, the width in the second direction D2 of the insulating structure 181 may decrease from an upper surface thereof toward a lower surface thereof. The width in the second direction D2 of the upper surface of the insulating structure 181 may be larger than the width in the second direction D2 of the lower surface of the insulating structure 181.

The insulating structure 181 may be disposed at a level lower than the first gate electrode 120 and the second gate electrode 220. Further, the insulating structure 181 may be disposed on lower surfaces of a lowermost first gate insulating film 130 and a lowermost second gate insulating film 230.

The insulating structure 181 may include the same material as the first field insulating film 105. Therefore, the insulating structure 181 may have the same etch selectivity as that of the material constituting the first field insulating film 105. For example, when the first field insulating film 105 includes silicon oxide (SiO), the insulating structure 181 may also include silicon oxide (SiO). However, this is merely an example, and the technical spirit of the present disclosure is not limited thereto.

The gate separation structure 171 may extend in the first direction D1. The gate separation structure 171 may be disposed between the first gate electrode 120 and the second gate electrode 220. The gate separation structure 171 may penetrate the first gate electrode 120 and the second gate electrode 220 in the first direction D1. The gate separation structure 171 may separate the first gate electrode 120 and the second gate electrode 220 from each other and may prevent electrical conduction between the first gate electrode 120 and the second gate electrode 220.

The gate separation structure 171 may extend in the third direction D3. The gate separation structure 171 may intersect a plurality of gate electrodes spaced apart in the third direction D3. In some embodiments, the gate separation structure 171 may be configured as a plurality of structures corresponding respectively to the plurality of gate electrodes spaced apart in the third direction D3.

The gate separation structure 171 may penetrate through an upper surface of the insulating structure 181. A lower surface of the gate separation structure 171 may be disposed on the insulating structure 181. For example, the lower surface of the gate separation structure 171 may penetrate through the upper surface of the insulating structure 181.

A maximum width of the insulating structure 181 in the second direction D2 may be larger than the width of the gate separation structure 171 in the second direction D2. For example, the width in the second direction D2 of the upper surface of the insulating structure 181 may be larger than the width in the second direction D2 of the lower surface of the gate separation structure 171. That is, the lower surface of the gate separation structure 171 may be positioned inside the insulating structure 181.

The lower surface of the gate separation structure 171 may be located at a level lower than an upper surface of the first field insulating film 105. The lower surface of the gate separation structure 171 may overlap the first field insulating film 105 in the second direction D2.

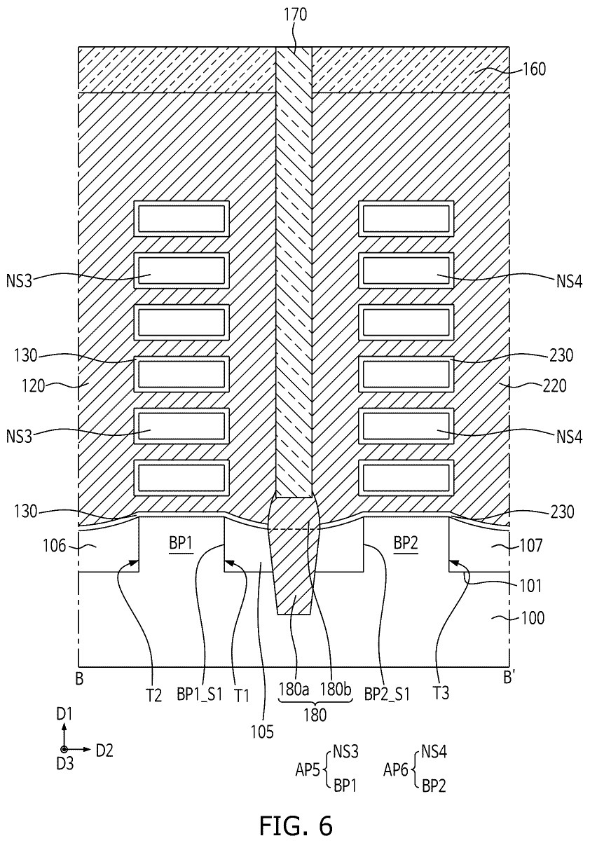

FIG. 6 is a cross-sectional view illustrating a semiconductor device according to some embodiments of the present disclosure. For convenience of explanation, a configuration different from what was described with reference to FIGS. 1 to 5 will be mainly described.

Referring to FIG. 6, a semiconductor device according to some embodiments of the present disclosure may include third nano sheets NS3, fourth nano sheets NS4, the first gate electrode 120, and the second gate electrode 220.

A fifth active pattern AP5 may include the first lower pattern BP1 and the plurality of third nano sheets NS3. A sixth active pattern AP6 may include the second lower pattern BP2 and the plurality of fourth nano sheets NS4.

The plurality of third nano sheets NS3 may be disposed on the first lower pattern BP1. The plurality of third nano sheets NS3 may be spaced apart from the first lower pattern BP1 in the first direction D1. Each of the third nano sheets NS3 may be spaced apart in the first direction D3. Although six third nano sheets NS3 are illustrated, the present disclosure is not limited thereto.

The plurality of fourth nano sheets NS4 may be disposed on the second lower pattern BP2. The plurality of fourth nano sheets NS4 may be spaced apart from the second lower pattern BP2 in the first direction D1. Each of the fourth nano sheets NS4 may be spaced apart in the first direction D1. Although six fourth nano sheets NS4 are illustrated, the present disclosure is not limited thereto.

Descriptions of materials for the third nano sheets NS3 and the fourth nano sheets NS4 may be the same as those for the first nano sheets NS1 and the second nano sheets NS2 described with reference to FIGS. 1 to 3.

The first gate electrode 120 may be disposed on the first field insulating film 105, the second field insulating film 106, and the first lower pattern BP1. The first gate electrode 120 may intersect the fifth active pattern AP5. The first gate electrode 120 may surround the third nano sheets NS3. The first gate electrode 120 may be disposed among the plurality of third nano sheets NS3. The first gate electrode 120 may be disposed between the third nano sheet NS3 positioned at the lowermost level among the plurality of third nano sheets NS3 and the first lower pattern BP1.

The second gate electrode 220 may be disposed on the first field insulating film 105, the third field insulating film 107, and the second lower pattern BP2. The second gate electrode 220 may intersect the sixth active pattern AP6. The second gate electrode 220 may surround the fourth nano sheets NS4. The second gate electrode 220 may be disposed among the plurality of fourth nano sheets NS4. The second gate electrode 220 may be disposed between the fourth nano sheet NS4 positioned at the lowermost level among the plurality of fourth nano sheets NS4 and the second lower pattern BP2.

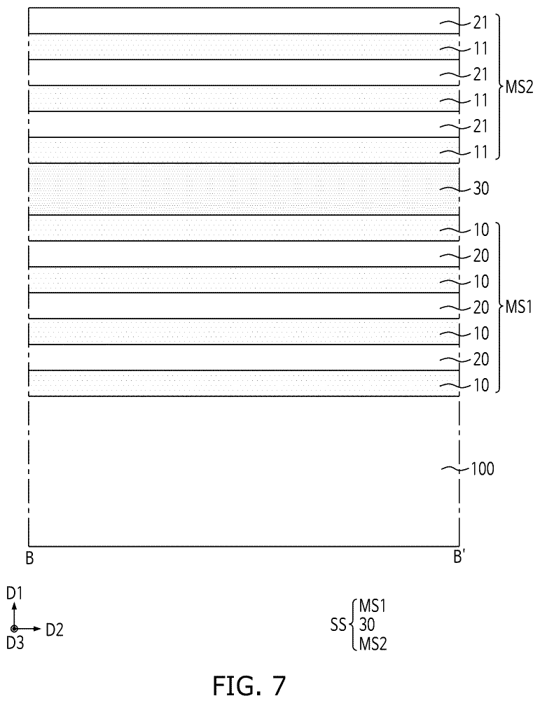

FIGS. 7 to 16 are diagrams illustrating a method of manufacturing a semiconductor device according to some embodiments of the present disclosure. For reference, FIGS. 7 to 16 may correspond to cross-sectional views taken along line B-B′ of FIG. 1.

Referring to FIG. 7, a substrate 100 may be provided. The substrate 100 may be a silicon substrate or silicon-on-insulator (SOI). Alternatively, the substrate 100 may include silicon germanium, silicon germanium on insulator (SGOI), indium antimonide, lead telluride compounds, indium arsenide, indium phosphide, gallium arsenide, or gallium antimonide, but the technical spirit of the present disclosure is not limited thereto.

Subsequently, a first stacked structure MS1, a separation layer 30, and a second stacked structure MS2 may be sequentially formed on an upper surface of the substrate 100. The first stacked structure MS1 may include a first sacrificial layer 10 and a first semiconductor layer 20 alternately stacked on the upper surface of the substrate 100. For example, each of the lowermost layer and the topmost layer of the first stacked structure MS1 may be formed of the first sacrificial layer 10. The second stacked structure MS2 may include a second sacrificial layer 11 and a second semiconductor layer 21 alternately stacked on an upper surface of the separation layer 30. For example, the lowermost layer of the second stacked structure MS2 may be formed of the second sacrificial layer 11. For example, the first sacrificial layer 10 and the second sacrificial layer 11 may include silicon germanium (SiGe). For example, the first semiconductor layer 20 and the second semiconductor layer 21 may include silicon (Si). For example, the separation layer 30 may include at least one of silicon nitride (SiN), silicon oxycarbonitride (SiOCN), silicon boron carbon nitride (SiBCN), silicon carbon nitride (SiCN), silicon oxynitride (SiON), or combinations thereof.

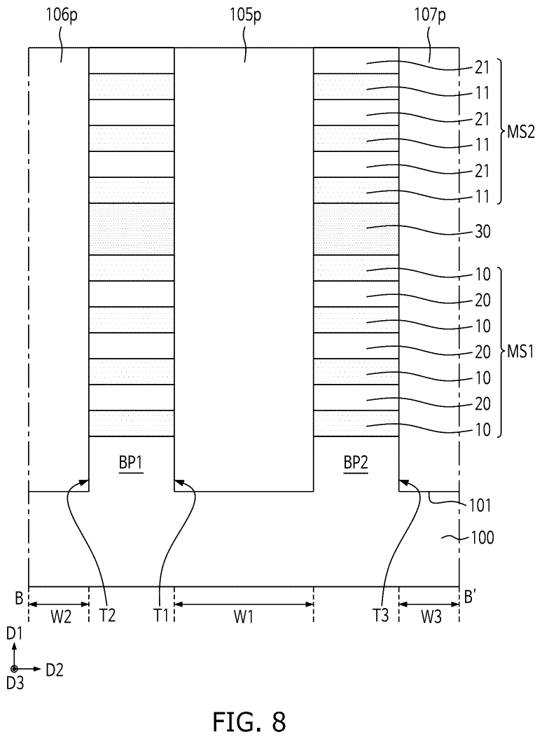

Referring to FIG. 8, portions of each of the first stacked structure MS1, the separation layer 30, and the second stacked structure MS2 may be etched. Portions of the substrate 100 may also be etched while the first stacked structure MS1, the separation layer 30, and the second stacked structure MS2 are etched. By such an etching process, first to third trenches T1, T2, T3 may be formed in the upper side of the substrate 100. The first trench T1 may be formed between the first lower pattern BP1 and the second lower pattern BP2, and each of the second trench T2 and the third trench T3 may be formed on one side of each of the first lower pattern BP1 and the second lower pattern BP2, respectively. Each of the first to third trenches T1, T2, T3 may have first to third widths W1, W2, W3 in the second direction D2. The first width W1 may be greater than the second width W2 or the third width W3. That is, the first trench T1 may have a width greater than that of the second and third trenches T2, T3. In some embodiments, the sizes of the second width W2 and the third width W3 may be the same.

Also, under the first stacked structure MS1 on the upper surface of the substrate 100, the first lower pattern BP1 and the second lower pattern BP2 may be defined. Each of the first lower pattern BP1 and the second lower pattern BP2 may protrude from the upper surface of the substrate 100 in a vertical direction D1. Each of the first lower pattern BP1 and the second lower pattern BP2 may extend in a third direction D3 parallel to the upper surface of the substrate 100.

Subsequently, an insulating material may be filled on the upper surface of the substrate 100. For example, first to third preliminary field insulating films 105p, 106p, 107p may be formed in the first to third trenches T1, T2, T3. Each of the first and second preliminary field insulating films 105p, 106p may surround sidewalls of the first lower pattern BP1 and the first stacked structure MS1, the separation layer 30, and the second stacked structure MS2. Each of the first and third preliminary field insulating films 105p, 107p may surround sidewalls of the second lower pattern BP2 and the first stacked structure MS1, the separation layer 30, and the second stacked structure MS2.

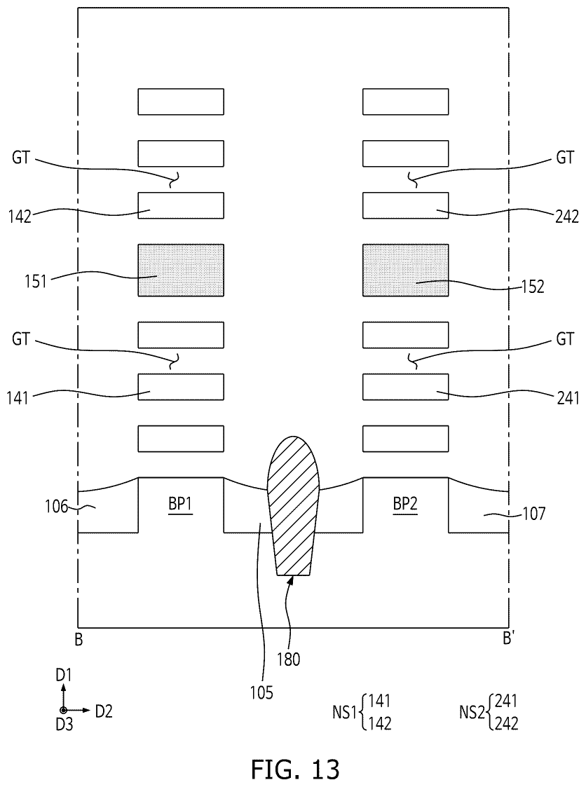

Meanwhile, due to the different widths of the first to third trenches T1, T2, T3, stress may be generated. On both sides of the first trench T1, which has a relatively large width in the second direction D2, an attractive force may be generated between the first stacked structure MS1, the separation layer 30, and the second stacked structure MS2 facing each other. Specifically, tensile stress may act on the first stacked structure MS1, the separation layer 30, and the second stacked structure MS2 located on opposite sides of the first trench T1 such that they move toward each other. Consequently, problems such as bending of the first nano sheets and the second nano sheets NS1, NS2 (see FIG. 13) may occur, and it is desirable to mitigate or prevent these problems.

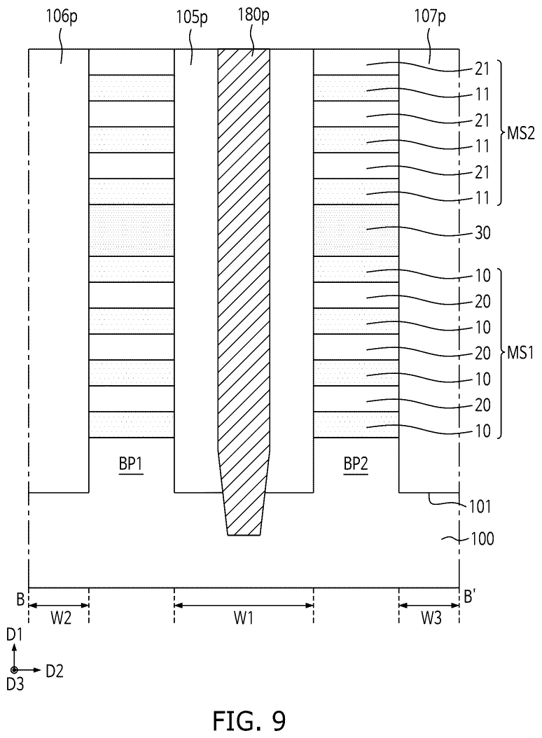

Referring to FIG. 9, in order to mitigate or prevent problems such as bending of the first nano sheets NS1 and the second nano sheets NS2, a preliminary insulating structure 180p may be formed.

To form the preliminary insulating structure 180p, a portion of the first preliminary field insulating film 105p may be etched. Through this etching process, a deep trench may be formed in the first preliminary field insulating film 105p. A bottom surface of the deep trench may be located lower than a bottom surface of the first preliminary field insulating film 105p. That is, the deep trench may be formed deeper than the first trench T1.

Subsequently, an insulating material may be filled inside the deep trench. The insulating material filled inside the deep trench may be different from the material constituting the first preliminary field insulating film 105p. For example, when the first preliminary field insulating film 105p includes silicon oxide, the insulating material filled inside the deep trench may be silicon nitride.

By filling the deep trench with the insulating material, the preliminary insulating structure 180p may be formed. The preliminary insulating structure 180p may extend in the first direction D1. The preliminary insulating structure 180p may extend to a greater extent in the first direction D1 than the first preliminary field insulating film 105p does. A lower portion of the preliminary insulating structure 180p may be tapered. In some embodiments, the preliminary insulating structure 180p may have a shape gradually narrowing from an upper portion toward a lower portion. A bottom surface of the preliminary insulating structure 180p may be located at a level lower than a bottom surface of the first preliminary field insulating film 105p. In some embodiments, through a planarization process, an upper surface of the preliminary insulating structure 180p may form a co-planar surface with the first preliminary field insulating film 105p.

The preliminary insulating structure 180p may be positioned in the first trench T1, which has a relatively large width. Since the preliminary insulating structure 180p may be located between the first nano sheets NS1 and the second nano sheets NS2 on both sides of the first trench T1, it may mitigate or prevent bending of the first nano sheets NS1 and the second nano sheets NS2 toward each other.

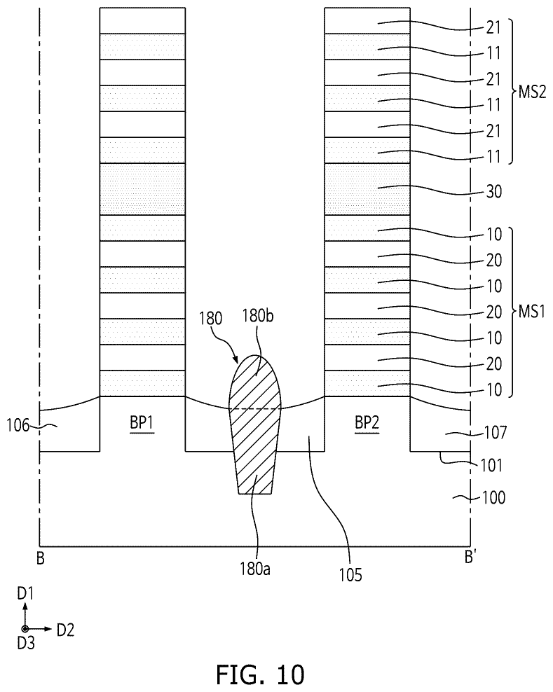

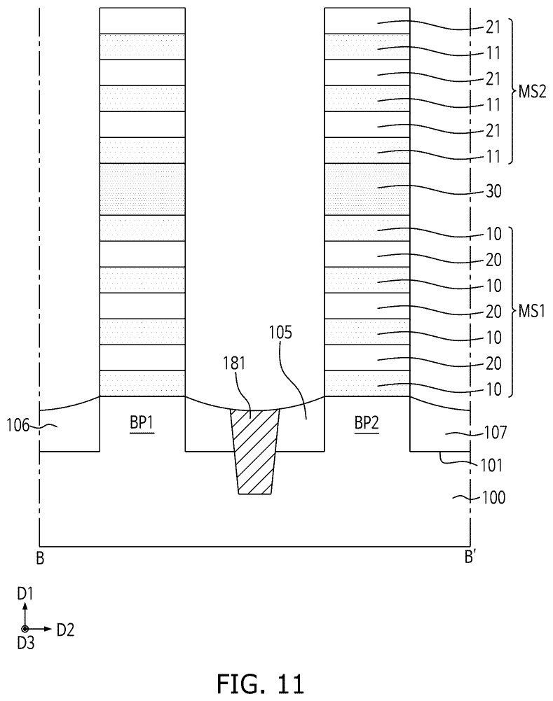

Referring to FIG. 10 or FIG. 11, an etching process may be performed on the first to third preliminary field insulating films 105p, 106p, 107p (see FIG. 9) and the preliminary insulating structure 180p (see FIG. 9). For example, the etching process may be performed by a wet etching method.

Through this etching process, portions of each of the first to third preliminary field insulating films 105p, 106p, 107p and the preliminary insulating structure 180p may be removed. For example, each of the first to third preliminary field insulating films 105p, 106p, 107p and the preliminary insulating structure 180p may be removed down to a level similar to the upper surfaces of the first lower pattern BP1 and the second lower pattern BP2. In this manner, by removing portions of each of the first to third preliminary field insulating films 105p, 106p, 107p and the preliminary insulating structure 180p, first to third field insulating films 105, 106, 107 and insulating structures 180, 181 may be formed.

Referring to FIG. 10, because the first to third preliminary field insulating films 105p, 106p, 107p (see FIG. 9) and the preliminary insulating structure 180p (see FIG. 9) include different materials, an etching rate may differ. For example, an etching process may be performed in which the material constituting the first to third preliminary field insulating films 105p, 106p, 107p may have a higher etch selectivity than the material constituting the preliminary insulating structure 180p. The first to third preliminary field insulating films 105p, 106p, 107p may be removed down to a level similar to the upper surfaces of the first lower pattern BP1 and the second lower pattern BP2, and the preliminary insulating structure 180p may be removed to a level higher than the first lower pattern BP1 and the second lower pattern BP2. That is, a portion of the insulating structure 180 may have a shape protruding in the first direction D1 from the first field insulating film 105. The portion of the insulating structure 180 embedded in the first field insulating film 105 may be referred to as the buried portion 180a, and the portion protruding from the first field insulating film 105 may be referred to as the protruding portion 180b.

Each of the first to third field insulating films 105, 106, 107 and the protruding portion 180b may have a rounded shape through the etching process. For example, each upper surface of the first to third field insulating films 105, 106, 107 may be recessed downward from the upper surfaces of the first lower pattern BP1 and the second lower pattern BP2. For example, the upper surface of each of the first to third field insulating films 105, 106, 107 may be a convex curved surface facing downward. Also, the protruding portion 180b of the insulating structure 180 may include a rounded upper surface. In some embodiments, the protruding portion 180b may include an angled portion.

Referring to FIG. 11, because the first to third preliminary field insulating films 105p, 106p, 107p (see FIG. 9) and the preliminary insulating structure 180p (see FIG. 9) include the same material, the etch rate may be the same. That is, the first to third preliminary field insulating films 105p, 106p, 107p and the preliminary insulating structure 180p may be removed at the same rate. For example, the first to third preliminary field insulating films 105p, 106p, 107p and the preliminary insulating structure 180p may be removed down to a level similar to the upper surfaces of the first lower pattern BP1 and the second lower pattern BP2. Through this etching process, the insulating structure 181 embedded in the first field insulating film 105 and the substrate 100 may be formed.

An upper surface of the insulating structure 181 may form a co-planar surface with an upper surface of the first field insulating film 105. For example, together with the upper surface of the first field insulating film 105, the upper surface of the insulating structure 181 may form a rounded upper surface. Specifically, the upper surface of the insulating structure 181 and the upper surface of the first field insulating film 105 may be a convex curved surface facing downward.

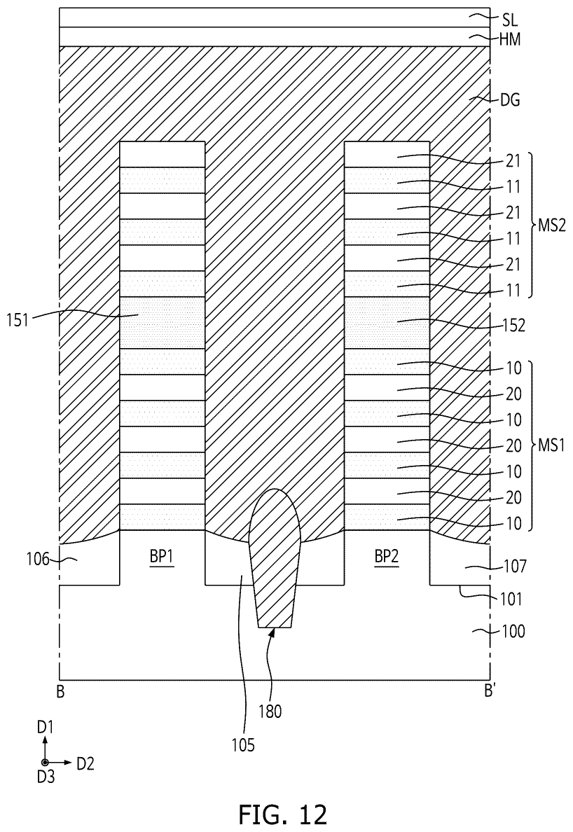

Referring to FIG. 12, a dummy gate DG may be formed in the space remaining after removal of the first to third preliminary field insulating films 105p, 106p, 107p and the preliminary insulating structure 180p. A hard mask pattern HM and a spacer layer SL may be formed on the dummy gate DG.

The dummy gate DG may be formed of polysilicon (poly Si). Using the hard mask pattern HM as a mask, the polysilicon may be patterned. The remaining dummy gate DG and the hard mask pattern HM, after patterning, may extend in the second direction D2. That is, the dummy gate DG and the hard mask pattern HM, each remaining after patterning, may intersect the stacked structures MS1, MS2. The spacer layer SL may extend along side surfaces of the dummy gate DG and the hard mask pattern HM, and along an upper surface of the second stacked structure MS2.

Referring to FIG. 13, by using an etching process, portions of the first stacked structure MS1, the first separation layer 30, and the second stacked structure MS2 may be removed to form a source/drain trench. A side surface of each of the first nano sheets NS1 and the second nano sheets NS2 may be exposed by the source/drain trench. The first semiconductor layer 20 and the second semiconductor layer 21 may be separated by the source/drain trench such that the first nano sheets NS1 and the second nano sheets NS2 are defined, and the first separation layer 30 may be defined as the first device isolation layer 151 and the second device isolation layer 152. During the etching process, a thickness of the hard mask pattern HM in the third direction may be reduced, and part of the spacer layer SL (see FIG. 12) may be removed to form the gate spacer 161 (see FIG. 3).

A lower source/drain pattern, a first etch stop layer, a first interlayer insulating film, an upper source/drain pattern, a second etch stop layer, and a second interlayer insulating film may be formed in the source/drain trench. The lower source/drain pattern and the upper source/drain pattern may be formed by an epitaxial growth method. In some embodiments, the source/drain pattern may be formed by at least one of an LPCVD (Low-pressure chemical vapor deposition) process, a SEG (selective epitaxial growth) process, or a CDE (cyclic deposition and etching) process using source materials containing group-IV semiconductor precursors.

Subsequently, the dummy gate DG may be removed, and the first sacrificial layer 10 and the second sacrificial layer 11 may be removed to form a gate trench GT. The gate trench GT may be formed by selectively removing the first sacrificial layer 10 and the second sacrificial layer 11 from the first nano sheets NS1 and the second nano sheets NS2. An etch selectivity difference between the first sacrificial layer 10 and the second sacrificial layer 11 and the first semiconductor layer 20 and the second semiconductor layer 21 may be used to selectively remove the first sacrificial layer 10 and the second sacrificial layer 11. A liquid or gaseous etchant may be used to selectively remove the first sacrificial layer 10 and the second sacrificial layer 11.

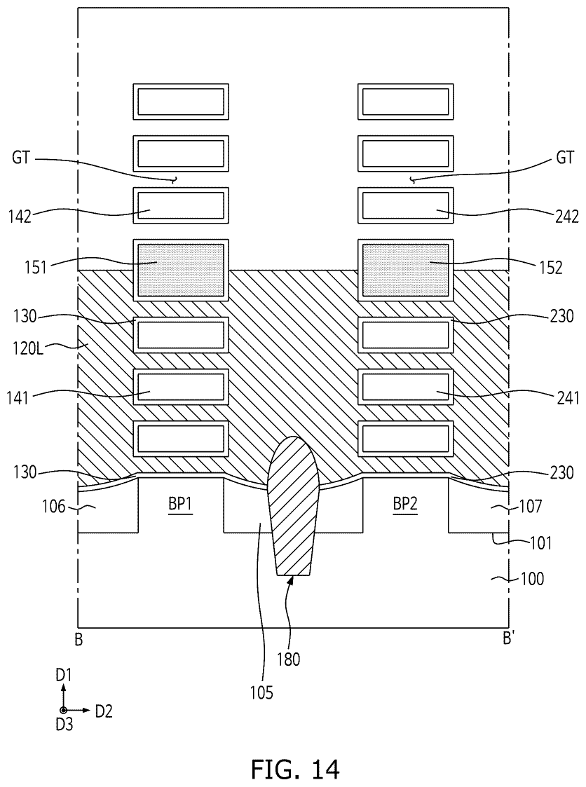

Referring to FIG. 14, a first gate insulating film 130 and a second gate insulating film 230 may be formed on the first lower pattern BP1 and the second lower pattern BP2, the first to third field insulating films 105, 106, 107, inside the gate trench GT, and on the first nano sheets NS1 and the second nano sheets NS2. For example, each of the first gate insulating film 130 and the second gate insulating film 230 may be formed by an atomic layer deposition (ALD) process.

Subsequently, a lower gate electrode 120L may be formed on the first gate insulating film 130 and the second gate insulating film 230. The lower gate electrode 120L may surround the lower channel patterns 141, 241. An upper surface of the lower gate electrode 120L may overlap the first device isolation layer 151 and the second device isolation layer 152 in the second direction D2. The lower gate electrode 120L may fill a space between adjacent lower channel patterns 141, 241. In addition, the lower gate electrode 120L may fill a space between the first lower pattern BP1 and the first lower channel pattern 141, a space between the second lower pattern BP2 and the second lower channel pattern 241, and a space between the first device isolation layer 151 and the first lower channel pattern 141, and a space between the second device isolation layer 152 and the second lower channel pattern 241.

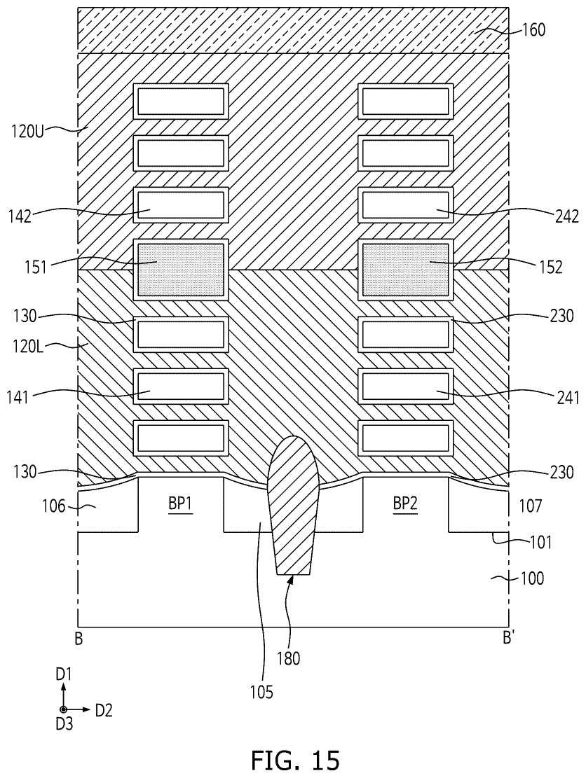

Referring to FIG. 15, an upper gate electrode 120U may be formed on the lower gate electrode 120L, on the first gate insulating film 130, and on the second gate insulating film 230. The upper gate electrode 120U may surround the upper channel patterns 142, 242. A lower surface of the upper gate electrode 120U may overlap the first device isolation layer 151 and the second device isolation layer 152 in the second direction D2. The upper gate electrode 120U may fill a space between adjacent upper channel patterns 142, 242. In addition, the upper gate electrode 120U may fill a space between the first device isolation layer 151 and the first upper channel pattern 142, and a space between the second device isolation layer 152 and the second upper channel pattern 242. The upper gate electrode 120U may fill a space between adjacent gate spacers 161.

Subsequently, a capping pattern 160 may be formed on the upper gate electrode 120U.

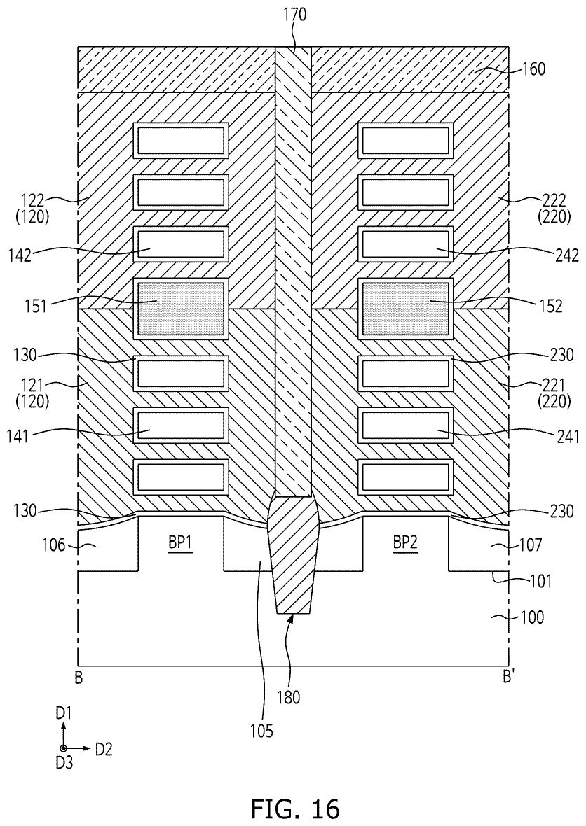

Referring to FIG. 16, a gate separation structure 170 that penetrates the lower gate electrode 120L, the upper gate electrode 120U, and the capping pattern 160 in the first direction D1 may be formed.

In order to form the gate separation structure 170, a gate separation trench may be formed to penetrate the lower gate electrode 120L, the upper gate electrode 120U, and the capping pattern 160 in the first direction D1. An etching process may be performed to remove portions of the lower gate electrode 120L, the upper gate electrode 120U, and the capping pattern 160. The etching process may be performed at a position in which the lower gate electrode 120L, the upper gate electrode 120U, and the capping pattern 160 are aligned with the insulating structure 180 in the first direction D1. The gate separation trench may be formed to have a width smaller than a maximum width of the insulating structure 180 in the second direction D2.

Part of the upper surface of the insulating structure 180 may be exposed through the gate separation trench. The gate separation trench may remove part of the insulating structure 180. That is, a lower surface of the gate separation structure 170 formed in the gate separation trench may contact the insulating structure 180. Specifically, the lower surface of the gate separation structure 170 may be located at a level lower than a topmost portion of the insulating structure 180.

Subsequently, by filling the gate separation trench with an insulating material, the gate separation structure 170 may be formed. The gate separation structure 170 may separate the first gate electrode 120 and the second gate electrode 220. By means of the gate separation structure 170, the first gate electrode 120 surrounding the first nano sheets NS1 and the second gate electrode 220 surrounding the second nano sheets NS2 may be defined, respectively.

Although the present disclosure has been described above with reference to limited embodiments and drawings, the present disclosure is not limited thereto, and it will be apparent to those of ordinary skill in the art that various modifications and variations are possible within the technical spirit of the present disclosure and within the equivalents of the claims to be described below.

What is claimed is:

1. A semiconductor device comprising:
a substrate;
a first lower pattern and a second lower pattern protruding from an upper surface of the substrate in a first direction substantially perpendicular to the upper surface of the substrate;
a first trench between the first lower pattern and the second lower pattern;
a plurality of first nano sheets stacked on the first lower pattern;
a plurality of second nano sheets stacked on the second lower pattern and spaced apart in the first direction;
a first gate electrode surrounding the plurality of first nano sheets, and a second gate electrode surrounding the plurality of second nano sheets;
a first field insulating film in the first trench;
an insulating structure penetrating the first field insulating film and the upper surface of the substrate in the first direction, the insulating structure comprising a buried portion embedded in the first field insulating film and in the substrate; and
a gate separation structure extending in the first direction between the first gate electrode and the second gate electrode and disposed on the insulating structure,
wherein the buried portion has a width in a second direction, which is substantially perpendicular to the first direction, that decreases from a top portion toward a bottom portion of the buried portion.

2. The semiconductor device according to claim 1, wherein the insulating structure further comprises a protruding portion on the buried portion and protruding from the first field insulating film.

3. The semiconductor device according to claim 2, wherein the protruding portion has a rounded upper surface.

4. The semiconductor device according to claim 1, wherein the first field insulating film comprises silicon oxide, and the insulating structure comprises silicon nitride.

5. The semiconductor device according to claim 1, wherein an upper surface of the buried portion is substantially coplanar with an upper surface of the first field insulating film.

6. The semiconductor device according to claim 5, wherein the upper surface of the buried portion and the upper surface of the first field insulating film form a convex curved surface facing downward.

7. The semiconductor device according to claim 1, wherein the gate separation structure penetrates through an upper surface of the insulating structure.

8. The semiconductor device according to claim 1, wherein the plurality of first nano sheets comprises a first lower channel pattern and a first upper channel pattern, and
the plurality of second nano sheets comprises a second lower channel pattern and a second upper channel pattern, and
the semiconductor device further comprises:
a first device isolation layer between the first lower channel pattern and the first upper channel pattern, and
a second device isolation layer between the second lower channel pattern and the second upper channel pattern.

9. The semiconductor device according to claim 8, wherein the first gate electrode comprises a first lower gate electrode surrounding the first lower channel pattern and a first upper gate electrode surrounding the first upper channel pattern, and
the second gate electrode comprises a second lower gate electrode surrounding the second lower channel pattern and a second upper gate electrode surrounding the second upper channel pattern,
the first lower gate electrode and the first upper gate electrode include different materials, and
the second lower gate electrode and the second upper gate electrode include different materials.

10. The semiconductor device according to claim 9, further comprising:
a first gate isolation layer between the first lower gate electrode and the first upper gate electrode, and
a second gate isolation layer between the second lower gate electrode and the second upper gate electrode.

11. The semiconductor device according to claim 1, wherein the first trench has a first width in the second direction, and
the semiconductor device further comprises
a second trench spaced in the second direction from the first trench and having a second width smaller than the first width.

12. The semiconductor device according to claim 11, further comprising a second field insulating film in the second trench,
wherein a side surface of the second field insulating film contacts the first lower pattern.

13. The semiconductor device according to claim 12, further comprising:
a third trench spaced in the second direction from the first trench and having a third width smaller than the first width, and
a third field insulating film in the third trench,
wherein a side surface of the third field insulating film contacts the second lower pattern.

14. A semiconductor device comprising:
a substrate;
a first lower pattern and a second lower pattern protruding in a first direction from an upper surface of the substrate and spaced apart from each other in a second direction substantially perpendicular to the first direction;
a first field insulating film on the upper surface of the substrate between the first lower pattern and the second lower pattern;
a plurality of first nano sheets stacked on the first lower pattern;
a plurality of second nano sheets stacked on the second lower pattern and spaced apart in the first direction;
a first gate electrode surrounding the plurality of first nano sheets, and a second gate electrode surrounding the plurality of second nano sheets;
an insulating structure penetrating through the first field insulating film and the upper surface of the substrate in the first direction; and
a gate separation structure extending in the first direction between the first gate electrode and the second gate electrode,
wherein the insulating structure comprises:
a buried portion embedded in the first field insulating film and the substrate and having a width in the second direction that decreases from a top portion toward a bottom portion of the buried portion, and
a protruding portion on the buried portion and protruding from the first field insulating film, and
wherein the gate separation structure is on the protruding portion.

15. The semiconductor device according to claim 14, further comprising:
a second field insulating film on the upper surface of the substrate and on a side surface of the first lower pattern, and
a third field insulating film on the upper surface of the substrate and on a side surface of the second lower pattern,
wherein the width of the first field insulating film in the second direction is greater than a width of the second field insulating film or a width of the third field insulating film in the second direction.

16. The semiconductor device according to claim 14, wherein the plurality of first nano sheets comprises a first lower channel pattern and a first upper channel pattern,
the plurality of second nano sheets comprises a second lower channel pattern and a second upper channel pattern,
the first gate electrode comprises a first lower gate electrode surrounding the first lower channel pattern and a first upper gate electrode surrounding the first upper channel pattern and including a material different from a material of the first lower gate electrode, and
the second gate electrode comprises a second lower gate electrode surrounding the second lower channel pattern and a second upper gate electrode surrounding the second upper channel pattern and including a material different from a material of the second lower gate electrode.

17. The semiconductor device according to claim 14, further comprising a capping pattern covering upper surfaces of each of the first gate electrode and the second gate electrode,
wherein the gate separation structure penetrates the capping pattern in the first direction.

18. The semiconductor device according to claim 14, wherein a maximum width of the protruding portion in the second direction is greater than a width of the gate separation structure in the second direction.

19. The semiconductor device according to claim 14, wherein the gate separation structure penetrates through an upper surface of the insulating structure and is spaced apart from an upper surface of the first field insulating film in the first direction.

20. A semiconductor device comprising:
a substrate;
a first lower pattern and a second lower pattern protruding from an upper surface of the substrate in a first direction substantially perpendicular to the upper surface of the substrate;
a first trench having a first width between the first lower pattern and the second lower pattern;
a second trench having a second width smaller than the first width and spaced apart from the first trench in a second direction substantially perpendicular to the first direction;
a first lower channel pattern and a first upper channel pattern stacked on the first lower pattern to be spaced apart in the first direction;
a second lower channel pattern and a second upper channel pattern stacked on the second lower pattern to be spaced apart in the first direction;
a first lower gate electrode surrounding the first lower channel pattern and a first upper gate electrode surrounding the first upper channel pattern;
a second lower gate electrode surrounding the second lower channel pattern and a second upper gate electrode surrounding the second upper channel pattern;
a first field insulating film in the first trench and a second field insulating film in the second trench;
an insulating structure penetrating the first field insulating film and the upper surface of the substrate in the first direction; and
a gate separation structure extending in the first direction and disposed on the insulating structure,
wherein the insulating structure comprises:
a buried portion embedded in the first field insulating film and the substrate and having a width in the second direction that decreases from a top portion toward a bottom portion of the buried portion, and
a protruding portion on the buried portion to protrude from the first field insulating film and having a rounded upper surface, and
wherein the gate separation structure penetrates through the upper surface of the protruding portion.
